(19) United States
(12) Patent Application Publication
(10) Pub. No.: US 2004/0227141 A1
(43) Pub. Date: Nov. 18, 2004

(54) Light emitting device having a high resistivity cushion layer

(75) Inventors: Ming-Jiunn Jou, Hsinchu (TW); Ming-Ta Chin, Hsinchu (TW); Biing-Jye Lee, Hsinchu (TW)

Correspondence Address: JONES DAY, Suite 4600, 555 W. Fifth Street, Los Angeles, CA, 90013-1025, US

(73) Assignee: Epistar Corporation

(21) Appl. No.: 10/767,402

(22) Filed: Jan. 29, 2004

(30) Foreign Application Priority Data
Jan. 30, 2003 (TW) 09210297

(51) Int. Cl. H01L 27/15

(52) U.S. Cl. 257/79

(57) ABSTRACT

A light emitting device having a high resistivity cushion layer, comprising a substrate; a first cladding layer formed on the substrate; an active layer formed on the first cladding layer; a second cladding layer formed on the active layer; a high resistivity cushion layer formed on the second cladding layer and having a resistivity higher than that of the second cladding layer; a contact layer formed on the high resistivity cushion layer; and a transparent conductive layer formed on the contact layer.

### BACKGROUND OF THE INVENTION

1. Field of the Invention

The present invention relates to a light emitting device, and more particularly to a light emitting device having a high resistivity cushion layer.

2. Description of the Prior Art

A light emitting diode (LED) of U.S. Pat. No. 5,008,718 issued to Fletcher, et al., is shown in FIG. 1. The LED 1 comprises a bottom metal electrode 26, an n-type substrate 20 of GaAs, a conventional double heterostructure 14 of AlGaInP, a p-type window layer 24, and a top metal electrode 25. The double heterostructure 14 of AlGaInP comprises a bottom cladding layer 21 of n-type AlGaInP, an active layer 22 of AlGaInP, and a top cladding layer 23 of p-type AlGaInP. A window layer 24 is formed directly adjoining the top cladding layer 23. The window layer 24 is made from a semiconductor different from AlGaInP and has an electrical resistivity lower than the AlGaInP active layers (preferably by an order of magnitude) for evenly distributing current and a bandgap greater than the active layers to minimize the amount of light emitted by the active layer 22 of the LED that is absorbed in the window layer. The resistivity of the window layer 24 is lowered by doping it with a high concentration of carriers. As a result, however, a portion of light from the active layer 22 will be absorbed by the window layer 24 because it is heavily doped, thereby reducing brightness of the LED. In addition, much of the light emitted by the active layer 22 directly under the top electrode 25 is shielded by the top electrode, thereby further compromising the efficiency of the device.

In contemplating how to solve the above mentioned problems, the inventors conceived an inventive concept of providing a light emitting device with a high resistivity cushion layer instead of the low resistivity window layer, such as the window layer 24 of FIG. 1 and as shown and described in U.S. Pat. No. 5,008,718. Because the high resistivity cushion layer has a low carrier concentration, it has good transparency. Therefore less light from the active layer will be absorbed when passing the cushion layer and an LED of higher brightness can be obtained.

### SUMMARY OF THE INVENTION

An object of the invention is to provide a light emitting device having a high resistivity cushion layer. Because the high resistivity cushion layer has a comparatively low carrier concentration, it also has improved transparency. Therefore less light from the active layer will be absorbed when passing the cushion layer and a light emitting device of higher brightness can be obtained.

To achieve these and other objects, a light emitting device having a high resistivity cushion layer in accordance with a preferred embodiment of the invention comprises a substrate; a first cladding layer formed on the substrate; an active layer formed on the first cladding layer; a second cladding layer formed on the active layer; a cushion layer formed on the second cladding layer having a resistivity higher than that of the second cladding layer; a contact layer formed on the high resistivity cushion layer; and a transparent conductive layer formed on the contact layer.

Other features, objects and advantages of the present invention will become apparent from the following detailed description of preferred embodiments taken together with the accompanying figures.

### BRIEF DESCRIPTION OF THE DRAWINGS

FIG. 1 is a schematic diagram illustrating a prior art LED;

FIG. 2 is a schematic diagram illustrating a light emitting device in accordance with a preferred embodiment of the invention;

FIG. 3 is a schematic diagram illustrating a light emitting device in accordance with another preferred embodiment of the invention;

FIG. 4 is a schematic diagram illustrating a light emitting device in accordance with yet another preferred embodiment of the invention; and

FIG. 5 is a schematic diagram illustrating a light emitting device in accordance with still another preferred embodiment of the invention.

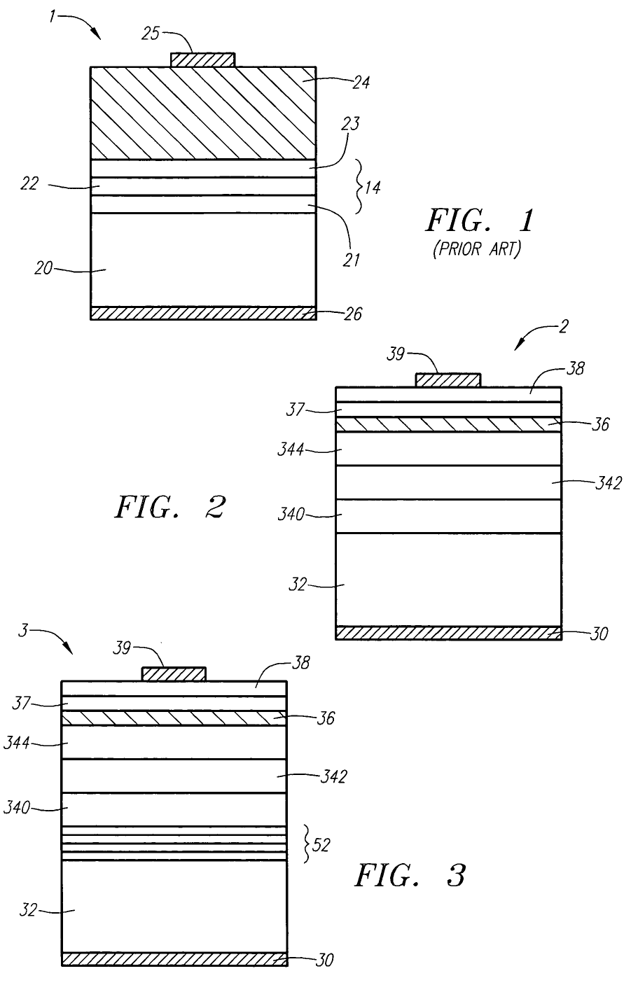

### DETAILED DESCRIPTION OF THE INVENTION

FIG. 2 illustrates a light emitting device 2 having a high resistivity cushion layer in accordance with a preferred embodiment of the invention. The light emitting device 2 of the present embodiment is a surface emitting device and comprises a first electrode 30; a semiconductor substrate 32 disposed on the first electrode; a first cladding layer 340 formed on the substrate 32; an active layer 342 formed on the first cladding layer 340; a second cladding layer 344 formed on the active layer 342; a cushion layer 36 formed on the second cladding layer 344, wherein the resistivity of the cushion layer 36 is higher than that of the second cladding layer 344; a contact layer 37 formed on the cushion layer 36; a transparent conductive layer 38 formed on the contact layer 37 and forming an ohmic contact with the contact layer 37; and a second electrode 39 formed on the transparent conductive layer 38. In this arrangement, and beginning with the substrate 32, the substrate 32 is followed by the cladding layer 340, which is followed by the active layer 342, which is followed by the cladding layer 344, which is followed by the cushion layer 36, which is followed by the contact layer 37, which is followed by the transparent conductive layer 38.

FIG. 3 illustrates a light emitting device 3 having a high resistivity cushion layer in accordance with another preferred embodiment of the invention. The structure of light emitting device 3 is the same as light emitting device 2 described in connection with FIG. 2 except that a distributed Bragg reflector (“DBR”) 52 has been formed on the substrate 32 so as to be interposed between the substrate 32 and the first cladding layer 340.

As illustrated by the embodiment shown in FIG. 3, although each layer is formed or disposed on a preceding layer in the light emitting device, the term “on” for purposes of the present disclosure does not imply or require the described layers to be adjoining one another. In other words, other layers may be interposed between the individually described layers or the described layers and the substrate. For example, DBR 52 is interposed between the substrate 32 and first cladding layer 340. It may be desirable to interpose other layers between the first electrode 30 and second electrode 39, or, more particularly, between the first cladding layer 340 and the second electrode 39 to, for example, improve or alter the electrical, optical, or physical properties of the device.

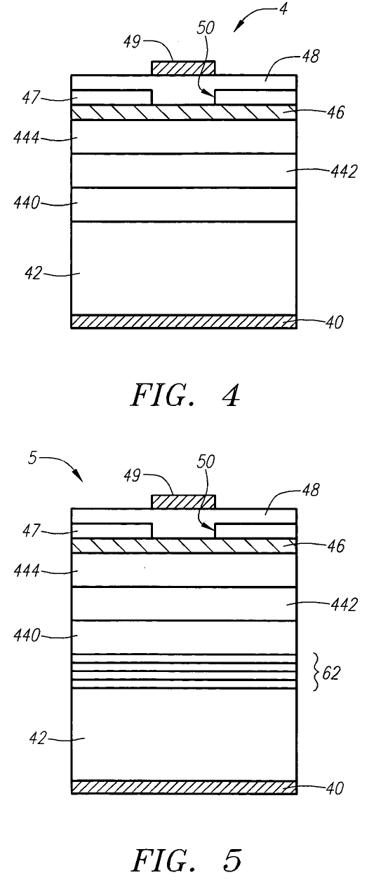

FIG. 4 illustrates a light emitting device 4 having a high resistivity cushion layer in accordance with another preferred embodiment of the invention. The light emitting device 4 of the present embodiment is a surface emitting device and comprises a first electrode 40; a semiconductor substrate 42 formed on the first electrode 40; a first cladding layer 440 formed on the substrate 42; an active layer 442 formed on the first cladding layer 440; a second cladding layer 444 formed on the active 442; a cushion layer 46 formed on the second cladding layer 46, wherein the resistivity of the cushion layer 46 is higher than that of the second cladding layer 444; a contact layer 47 formed on the cushion layer 46 and having a central through hole 50 being formed in the contact layer 47; a transparent conductive layer 48 formed on the contact layer 47 and filling up the central through hole 50, thereby forming an interface with the cushion layer 46; and a second electrode 49 formed, approximately in alignment with the through hole 50, on a portion of the transparent conductive layer 48. In this arrangement, and beginning with the substrate 42, the substrate 42 is followed by the cladding layer 440, which is followed by the active layer 442, which is followed by the cladding layer 444, which is followed by the cushion layer 46, which is followed by the contact layer 47, which is followed by the conductive layer 48.

Further as illustrated by the embodiment shown in FIG. 5, although each layer is formed or disposed on a preceding layer in the light emitting device, the term “on” for purposes of the present disclosure does not imply or require the described layers to be adjoining one another. In other words, other layers may be interposed between the individually described layers or the described layers and the substrate. It may be desirable to interpose other layers between first electrode 40 and second electrode 49, or, more particularly, between the first cladding layer 440 and the second electrode 49 to, for example, improve or alter the electrical, optical, or physical properties of the device.

FIG. 5 illustrates a light emitting device 5 having a high resistivity cushion layer in accordance with still another preferred embodiment of the invention. The structure of light emitting device 5 is the same as light emitting device 4 described in connection with FIG. 4 except that a DBR 62 has been formed on the substrate 42 so as to be interposed between the substrate 42 and the first cladding layer 440.

In the foregoing embodiments, the substrate 32 or 42 preferably comprises a semiconductor material selected from a group consisting of Si, Ge, GaAs, GaP, AlGaAs, and GaAsP and is preferably n-type. More preferably the substrate comprises n-type GaAs. Further, the substrate 32 or 42 is preferably between approximately 150 to approximately 350 microns in thickness and more preferably between approximately 150 to approximately 300 microns in thickness. The substrate 32 or 42 may be doped with a carrier concentration between approximately 1×10¹⁷ cm⁻³ and 4×10¹⁸ cm⁻³. A suitable n-type carrier atom for the substrate includes, by way of example, silicon.

The active layer 342 or 442 comprises AlGaInP. Preferably the active layer comprises AlGaInP having the formula AlₓGa_{y}In_{(1-x-y)}P, where 0≦x,y≦1. The active layer is preferably between 0.3 and 0.75 microns in thickness, and more preferably between 0.3 and 0.7 microns in thickness. Typically the active layer is undoped. The active layer 342 or 442 may be made of a multiple quantum well (“MQW”) structure to improve light output and the efficiency of the device.

The first cladding layer 340 or 440 preferably comprises an n-type semiconductor, such as an n-type AlGaInP or AlInP. More preferably the first cladding layer comprises n-type semiconductor having the formula Al(x)In(1−x)P, where x is 0.5. The first cladding layer is typically between 0.4 and 1 micron(s) in thickness, and more preferably between 0.4 and 0.6 microns in thickness. The first cladding layer 340 or 440 is preferably doped with a carrier concentration between 1×10¹⁸ cm⁻³ and 3×10¹⁸ cm⁻³. As will be appreciated by those skilled in the art, a variety of doping elements may be used, depending on the composition of the first cladding layer, to achieve an n-type first cladding layer. When the first cladding layer 340 or 440 comprises AlInP, silicon is preferably used as the doping element.

The second cladding layer 344 or 444 preferably comprises p-type semiconductor, such as p-type AlGaInP or AlInP. More preferably the second cladding layer comprises an p-type semiconductor having the formula Al(x)In(1−x)P, where x is 0.5. The second cladding layer is typically between 0.4 and 1 microns in thickness, and more preferably between 0.4 and 0.6 microns. The second cladding layer 344 or 444 is preferably doped with a carrier concentration between 5×10¹⁷ and 1×10¹⁸ cm⁻³. A variety of doping elements may be used, depending on the composition of the second cladding layer, to achieve a p-type second cladding layer. When the second cladding layer 344 or 444 comprises AlInP, magnesium is preferably used as the doping element.

The cushion layer 36 or 46 preferably comprises a p-type semiconductor. More preferably the cushion layer comprises a p-type semiconductor material selected from a group consisting of GaP, GaAsP, GaInP, and AlGaAs. In addition, p-type AlGaInP may also be used as the cushion layer. A particularly preferred semiconductor material for the cushion layer is GaP. The cushion layer is preferably less than two microns in thickness. The cushion layer is preferably doped with a carrier concentration of between 1×10¹⁷ cm⁻³ and 2×10¹⁸ cm⁻³. However, any doping level that results in a cushion layer 36 or 46 that has a greater resistivity than that of second cladding layer 344 or 444, respectively, may be used. Further, while a variety of doping elements may be used, depending on the composition of the cushion layer, to achieve a p-type cushion layer, a preferred doping element for the cushion layer is magnesium.

The cushion layer 36 or 46 serves a number of functions in the light emitting devices of the present invention. For example, the layer provides a buffer or cushion between the electrode and transparent conductive layer on the one hand and the second cladding layer on the other hand, thus preventing bonding damage to the second cladding layer and the active layer of the light emitting device. In addition, because the cushion layer 36 or 46 of the present invention will typically have a carrier concentration less than that employed in prior art window layers, the cushion layer 36 or 46 will tend to exhibit improved light transparency, particularly at shorter wavelengths in the visible spectrum. Further, the low carrier concentration, and hence high resistivity, of the cushion layer 46 also minimizes the amount of current that flows toward the portion of the cushion layer directly under the front electrode 49 as the current passes through the cushion layer 46. Consequently, by employing the embodiments shown in FIGS. 4 and 5, it is possible to reduce the amount of light shielding by the front electrode 49 below that which occurs in prior art devices that employ window layers with a resistivity that is lower than that of the second cladding layer. Finally, when a Schottky barrier is to be included in a light emitting device according to the present invention, the cushion layer 46 can also serve as an etch stop or to control etching, thereby preventing damage from occurring to the second cladding layer 444 and the active layer 442 during the fabrication process.

The contact layer 37 or 47 preferably comprises a material selected from a group consisting of GaP, GaAsP, GaInP, GaAs, AlGaAs, Be/Au, Zn/Au, Ge/Au and Ge. More preferably the contact layer comprises p-type semiconductor having the formula Ga(x)In(1−x)P, where 0≦x≦1. The contact layer 37 or 47 is preferably between 0.03 and 0.07 microns in thickness and, when formed from a semiconductor, is preferably doped with a carrier concentration at greater than 1×10¹⁹ cm⁻³. In general, the concentration of carriers in the contact layer should be sufficient so as to permit the contact layer to form an ohmic contact with the transparent conductive layer 38 or 48. Further, while a variety of doping elements may be used, a preferred doping element for the contact layer is carbon.

The transparent conductive layer 38 or 48 preferably comprises a material selected from a group consisting of indium tin oxide, cadmium tin oxide, antimony tin oxide, magnesium oxide, zinc oxide and zinc tin oxide. Other materials that are suitable for the transparent conductive layer 38 or 48 include, for example, tin oxide and indium oxide. Most preferably, the transparent conductive layer comprises indium tin oxide. The transparent conductive layer 38 or 48 is preferably between approximately 0.1 and 5 microns in thickness, and more preferably between approximately 0.1 and 0.3 microns.

Each of the layers described above, except for the transparent conductive layer 38 or 48 and the electrodes 30, 39, 40, 49, may, for example, be grown using a metalorganic vapor phase epitaxy (MOVPE) method. The transparent conductive layer 38 or 48 may be formed by, for example, a sputtering or E-beam evaporation method.

In the embodiments illustrated in FIGS. 4 and 5, through hole 50 may be formed using conventional photolithographic techniques known in the art. For example, through hole 50 may be formed by etching a portion of the contact layer 47, following the application of a suitable mask, until the surface of the cushion layer 46 is exposed. Following the formation of the through hole 50, the mask is removed and transparent conductive layer 48 formed. The interface between the transparent conductive layer 48 and the cushion layer 46 results in a Schottky barrier, which acts as a current block.

Although the preferred embodiments of the invention have been illustrated and described in the above, it will be obvious to those skilled in the art that various modifications may be made without departing from the scope and spirit of the invention defined by the appended claims. For example, as illustrated in FIGS. 3 and 5, a DBR 52 or 62 can be formed between the substrate 32 or 42 and the first cladding layer 340 or 440. When a DBR is included, it preferably comprises an n-type semiconductor material selected from a group consisting of AlGaInP, AlGaAs, and AlAs and is preferably doped with a carrier concentration of between 1×10¹⁸ cm⁻³ and 3×10¹⁸ cm⁻³. Further, while the above embodiments have been described such that the substrate, first cladding layer and DBR are preferably n-type semiconductors and the second cladding layer, cushion layer and contact layer are preferably p-type semiconductors, it will be appreciated by those skilled in the art that the substrate, first cladding layer and DBR may alternatively be made from p-type semiconductors and the second cladding layer, cushion layer and contact layer from n-type semiconductors. Moreover, while each of the above described embodiments of the invention are surface emitting devices, the present invention can also be readily adapted to provide side emitting devices, or other devices which emit coherent or incoherent light.

What is claimed is:

1. A light emitting device having a high resistivity cushion layer, comprising:
a substrate;
a first cladding layer formed on the substrate;
an active layer formed on the first cladding layer;
a second cladding layer formed on the active layer;
a cushion layer formed on the second cladding layer and having a resistivity higher than that of the second cladding layer;
a contact layer formed on the cushion layer; and
a transparent conductive layer formed on the contact layer.

2. A light emitting device having a high resistivity cushion layer according to claim 1, wherein the active layer comprises AlGaInP.

3. A light emitting device having a high resistivity cushion layer according to claim 1, wherein the active layer comprises a multiple quantum well structure.

4. A light emitting device having a high resistivity cushion layer according to claim 1, wherein the cushion layer comprises a material selected from a group consisting of GaP, GaAsP, GaInP and AlGaAs.

5. A light emitting device having a high resistivity cushion layer according to claim 1, wherein the cushion layer comprises AlGaInP.

6. A light emitting device having a high resistivity cushion layer according to claim 1, wherein the contact layer comprises a material selected from a group consisting of GaP, GaAsP, GaInP, GaAs, AlGaAs, Be/Au, Zn/Au, Ge/Au and Ge.

7. A light emitting device having a high resistivity cushion layer according to claim 6, wherein the contact layer comprises a semiconductor material doped with carbon.

8. A light emitting device having a high resistivity cushion layer according to claim 1, wherein the transparent conductive layer comprises a material selected from a group consisting of indium tin oxide, cadmium tin oxide, antimony tin oxide, magnesium oxide, zinc oxide and zinc tin oxide.

9. A light emitting device having a high resistivity cushion layer according to claim 1, wherein the transparent conductive layer comprises a material selected from a group consisting of indium oxide and tin oxide.

10. A light emitting device having a high resistivity cushion layer according to claim 1, wherein the substrate comprises a material selected from a group consisting of Si, Ge, GaAs, GaP, AlGaAs and GaAsP.

11. A light emitting device having a high resistivity cushion layer according to claim 1, wherein the first cladding layer or the second cladding layer comprises AlGaInP or AlInP.

12. A light emitting device having a high resistivity cushion layer according to claim 1, further comprising a DBR formed between the substrate and the first cladding layer.

13. A light emitting device having a high resistivity cushion layer according to claim 12, wherein the DBR comprises a material selected from a group consisting of AlGaInP, AlGaAs and AlAs.

14. A light emitting device having a high resistivity cushion layer according to claim 1, wherein the device is a surface emitting device.

15. A light emitting device having a high resistivity cushion layer, comprising:
a first electrode;
a substrate formed on the first electrode;
a first cladding layer formed on the substrate;
an active layer formed on the first cladding layer;
a second cladding layer formed on the active layer;
a cushion layer formed on the second cladding layer and having a resistivity higher than that of the second cladding layer;
a contact layer formed on the cushion layer for providing an ohmic contact, the contact layer being formed with a through hole that exposes a portion of the cushion layer;
a transparent conductive layer formed on the contact layer and filling in the through hole in the contact layer; and
a second electrode formed on a portion of the transparent conductive layer, the second electrode being approximately aligned with the through hole in the contact layer.

16. A light emitting device having a high resistivity cushion layer according to claim 15, wherein the active layer comprises AlGaInP.

17. A light emitting device having a high resistivity cushion layer according to claim 15, wherein the active layer comprises a multiple quantum well structure.

18. A light emitting device having a high resistivity cushion layer according to claim 15, wherein the cushion layer comprises a material selected from a group consisting of GaP, GaAsP, GaInP and AlGaAs.

19. A light emitting device having a high resistivity cushion layer according to claim 15, wherein the cushion layer comprises AlGaInP.

20. A light emitting device having a high resistivity cushion layer according to claim 15, wherein the contact layer comprises a material selected from a group consisting of GaP, GaAsP, GaInP, GaAs, AlGaAs, Be/Au, Zn/Au, Ge/Au and Ge.

21. A light emitting device having a high resistivity cushion layer according to claim 20, wherein the contact layer comprises a semiconductor material doped with carbon.

22. A light emitting device having a high resistivity cushion layer according to claim 15, wherein the transparent conductive layer comprises a material selected from a group consisting of indium tin oxide, cadmium tin oxide, antimony tin oxide, magnesium oxide, zinc oxide and zinc tin oxide.

23. A light emitting device having a high resistivity cushion layer according to claim 15, wherein the transparent conductive layer comprises a material selected from a group consisting of indium oxide and tin oxide.

24. A light emitting device having a high resistivity cushion layer according to claim 15, wherein the substrate comprises a material selected from a group consisting of Si, Ge, GaAs, GaP, AlGaAs and GaAsP.

25. A light emitting device having a high resistivity cushion layer according to claim 15, wherein the first cladding layer or the second cladding layer comprises AlGaInP or AlInP.

26. A light emitting device having a high resistivity cushion layer according to claim 15, further comprising a DBR formed between the substrate and the first cladding layer.

27. A light emitting device having a high resistivity cushion layer according to claim 26, wherein the DBR comprises a material selected from a group consisting of AlGaInP, AlGaAs and AlAs.

28. A light emitting device having a high resistivity cushion layer according to claim 15, wherein the device is a surface emitting device.

29. A light emitting device having a high resistivity cushion layer, comprising:
a substrate;
an active layer;
a first cladding layer between the substrate and the active layer;
a second cladding layer;
a cushion layer, having a resistivity higher than the second cladding layer, wherein the second cladding layer is between the active layer and the cushion layer;
a transparent conductive layer; and
a contact layer interposed between at least a portion of the cushion layer and at least a portion of the transparent conductive layer.

30. A light emitting device having a high resistivity cushion layer according to claim 29, wherein the active layer comprises AlGaInP.

31. A light emitting device having a high resistivity cushion layer according to claim 29, wherein the active layer comprises a multiple quantum well structure.

32. A light emitting device having a high resistivity cushion layer according to claim 29, wherein the cushion layer comprises a material selected from a group consisting of GaP, GaAsP, GaInP and AlGaAs.

33. A light emitting device having a high resistivity cushion layer according to claim 29, wherein the cushion layer comprises AlGaInP.

34. A light emitting device having a high resistivity cushion layer according to claim 29, wherein the contact layer comprises a material selected from a group consisting of GaP, GaAsP, GaInP, GaAs, AlGaAs, Be/Au, Zn/Au, Ge/Au and Ge.

35. A light emitting device having a high resistivity cushion layer according to claim 34, wherein the contact layer comprises a semiconductor material doped with carbon.

36. A light emitting device having a high resistivity cushion layer according to claim 29, wherein the transparent conductive layer comprises a material selected from a group consisting of indium tin oxide, cadmium tin oxide, antimony tin oxide, magnesium oxide, zinc oxide and zinc tin oxide.

37. A light emitting device having a high resistivity cushion layer according to claim 29, wherein the transparent conductive layer comprises a material selected from a group consisting of indium oxide and tin oxide.

38. A light emitting device having a high resistivity cushion layer according to claim 29, wherein the substrate comprises a material selected from a group consisting of Si, Ge, GaAs, GaP, AlGaAs and GaAsP.

39. A light emitting device having a high resistivity cushion layer according to claim 29, wherein the first cladding layer or the second cladding layer comprises AlGaInP or AlInP.

40. A light emitting device having a high resistivity cushion layer according to claim 29, further comprising a DBR formed between the substrate and the first cladding layer.

41. A light emitting device having a high resistivity cushion layer according to claim 40, wherein the DBR comprises a material selected from a group consisting of AlGaInP, AlGaAs and AlAs.

42. A light emitting device having a high resistivity cushion layer according to claim 29, wherein the device is surface emitting.

43. A light emitting device having a high resistivity cushion layer, comprising:
a substrate;
an active layer;
a first cladding layer between the substrate and the active layer;
a second cladding layer;
a cushion layer having a resistivity higher than the second cladding layer, wherein the second cladding layer is between the active layer and the cushion layer;
a transparent conductive layer; and
a contact layer having a through hole interposed between a portion of the cushion layer and a first portion of the transparent conductive layer, and wherein a second portion of the transparent conductive layer fills in the through hole to form a Schottky barrier.

44. A light emitting device having a high resistivity cushion layer according to claim 43, wherein the active layer comprises Al GaInP.

45. A light emitting device having a high resistivity cushion layer according to claim 43, wherein the active layer comprises a multiple quantum well structure.

46. A light emitting device having a high resistivity cushion layer according to claim 43, wherein the cushion layer comprises a material selected from a group consisting of GaP, GaAsP, GaInP and AlGaAs.

47. A light emitting device having a high resistivity cushion layer according to claim 43, wherein the cushion layer comprises AlGaInP.

48. A light emitting device having a high resistivity cushion layer according to claim 43, wherein the contact layer comprises a material selected from a group consisting of GaP, GaAsP, GaInP, GaAs, AlGaAs, Be/Au, Zn/Au, Ge/Au and Ge.

49. A light emitting device having a high resistivity cushion layer according to claim 48, wherein the contact layer comprises a semiconductor material doped with carbon.

50. A light emitting device having a high resistivity cushion layer according to claim 43, wherein the transparent conductive layer comprises a material selected from a group consisting of indium tin oxide, cadmium tin oxide, antimony tin oxide, magnesium oxide, zinc oxide and zinc tin oxide.

51. A light emitting device having a high resistivity cushion layer according to claim 43, wherein the transparent conductive layer comprises a material selected from a group consisting of indium oxide and tin oxide.

52. A light emitting device having a high resistivity cushion layer according to claim 43, wherein the substrate comprises a material selected from a group consisting of Si, Ge, GaAs, GaP, AlGaAs and GaAsP.

53. A light emitting device having a high resistivity cushion layer according to claim 43, wherein the first cladding layer or the second cladding layer comprises AlGaInP or AlInP.

54. A light emitting device having a high resistivity cushion layer according to claim 43, further comprising a DBR formed between the substrate and the first cladding layer.

55. A light emitting device having a high resistivity cushion layer according to claim 54, wherein the DBR comprises a material selected from a group consisting of AlGaInP, AlGaAs and AlAs.

56. A light emitting device having a high resistivity cushion layer according to claim 43, wherein the device is surface emitting.

57. A device having a high resistivity cushion layer, comprising:
a transparent conductive layer disposed on a substrate, wherein at least a first cladding layer, an active layer, a second cladding layer, and a cushion layer having a resistivity higher than the second cladding layer are interposed between the substrate and transparent conductive layer in the referenced order, and further wherein a contact layer is interposed between at least a portion of the cushion layer and a at least a portion of the transparent conductive layer.

58. A light emitting device having a high resistivity cushion layer according to claim 58, wherein the device is surface emitting.
